(19) United States
(12) Patent Application Publication
(10) Pub. No.: US 2023/0127390 A1
(43) Pub. Date: Apr. 27, 2023

(54) POLISHING OF POLYCRYSTALLINE MATERIALS

(71) Applicant: ENTEGRIS, INC., Billerica, MA (US)

(72) Inventors: Rajiv K. Singh, Newberry, FL (US); Sunny De, Gainesville, FL (US)

(21) Appl. No.: 17/970,371

(22) Filed: Oct. 20, 2022

Related U.S. Application Data
(60) Provisional application No. 63/272,394, filed on Oct. 27, 2021.

(51) Int. Cl. B24B 1/04; C30B 33/00; B24B 37/24; C09G 1/02

(52) U.S. Cl. CPC B24B 1/04; C30B 33/00; B24B 37/24; C09G 1/02; C30B 29/04

(57) ABSTRACT

The invention provides methodology for final finishing of hard surfaces such as diamond surfaces. In this method, a smooth pad having a surface roughness of about 0.2 nm to about 100 nm, having, for example a thickness ranging from about 0.02 mm to about 5 mm, and a Shore D hardness of 30 or higher, is utilized in conjunction with known polishing slurries to provide diamond surfaces having superior smooth finishes.

### CROSS-REFERENCE TO RELATED APPLICATION

This application claims the benefit under 35 USC 119 of U.S. Provisional Patent Application No. 63/272,394, filed Oct. 27, 2021, the disclosure of which is hereby incorporated herein by reference in its entirety.

### TECHNICAL FIELD

The present invention relates generally to improved methods for polishing diamond and other hard surfaces.

### BACKGROUND

Microelectronic device wafers are used to form integrated circuits. The microelectronic device wafer includes a substrate, such as silicon, into which regions are patterned for deposition of different materials having insulative, conductive or semi-conductive properties. In order to obtain the correct patterning, excess material used in forming the layers on the substrate must be removed. Further, to fabricate functional and reliable circuitry, it is often important to prepare a flat or planar microelectronic wafer surface prior to subsequent processing. Thus, it is necessary to planarize and/or polish certain surfaces of a microelectronic device wafer.

Chemical Mechanical Polishing or Planarization (“CMP”) is a process in which material is removed from a surface of a microelectronic device wafer, and the surface is planarized and polished by coupling a physical process such as abrasion with a chemical process such as oxidation or chelation. In its most rudimentary form, CMP involves applying slurry, e.g., a solution of an abrasive and an active chemistry, to a polishing pad that buffs the surface of a microelectronic device wafer to achieve the removal, planarization, and polishing processes. It is not typically desirable for the removal or polishing process to be comprised of purely physical or purely chemical action, but rather the synergistic combination of both in order to achieve fast, uniform removal. In the fabrication of integrated circuits, the CMP slurry should also be able to preferentially remove films that comprise complex layers of metals and other materials so that highly planar surfaces can be produced for subsequent photolithography, patterning, etching and thin-film processing. In conventional CMP operations, a substrate carrier or polishing head is mounted on a carrier assembly and positioned in contact with a polishing pad in a CMP apparatus. The carrier assembly provides a controllable pressure to the substrate pressing the substrate against the polishing pad. The pad is moved relative to the substrate.

There is a need to improve the CMP polishing rate of hard materials such as diamond. Inter alia, diamond materials may be used as dielectrics, etch stops, or related functions for integrated circuits (ICs) and other related applications. It is generally important that the overall friction of the CMP process is low and essentially no polishing defects are generated on the surface of the substrate. Furthermore, as the pressure and velocity during polishing is increased, there is a need to decrease the temperature rise during the polishing process. A reduced temperature rise during the polishing process makes the process more stable and reproducible.

In particular, small area single crystal diamond (e.g., 5 mm to 50 mm) and large area polycrystalline diamond substrates (e.g., 25 mm to 150 mm) are being developed for many new applications such EUV lithography, production of gallium nitride (GaN) on diamond substrates for 6G communications, and diamond seeds for chemical vapor deposition of diamond for jewelry applications. The major challenges faced during polishing of such materials include the non-planarity of diamond grains. As the diamond grains are of various orientations, the chemical effect is different for different crystal directions resulting in a non-planar surface. New methods have to be developed to address these issues.

Certain hard slurry particles such as diamond, cubic boron nitride, silicon carbide, and boron carbide, are routinely applied to polish hard substrates such as diamond using a mechanical process such as lapping and grinding. The size of the particles generally controls the polishing rate (i.e., material removal). However, larger particles also tend to cause higher surface and subsurface damage, so that mechanical polishing processes may employ multiple steps. For example, initially larger-sized particles can be used in initial CMP step(s) followed by smaller and smaller size particles in later CMP step(s) in an attempt to improve the removal rate while limiting undesired surface damage. Nonetheless, a need remains for improvement in the overall surface finish of hard materials such as diamond.

### SUMMARY

In summary, the invention provides a method for final finishing of hard surfaces such as diamond surfaces. In this method, a smooth pad having a surface roughness (Ra) of about 0.2 nm to about 100 nm, having, for example a thickness ranging from about 0.02 mm to about 5 mm, and a Shore D hardness of 30 or higher, is utilized in conjunction with known polishing slurries to provide diamond surfaces having superior smooth finishes. The pad can be made of synthetic materials such as a poly(vinyl chloride) (PVC) or other polymers. The pads utilized in the method of the invention are extremely smooth (0.2 nm to 100 nm average roughness (Ra)) compared to conventional pads utilized for final polishing of diamond surfaces which have a higher roughness profile (>100 nm). In the method of the invention, we have polished diamond surfaces using CMP slurries and found them to have flatter topography and lower roughness in polycrystalline diamond films and polycrystalline silicon carbide.

### BRIEF DESCRIPTION OF THE DRAWINGS

FIG. 1 (Comparative) is an optical profilometer 3D view of a polished diamond substrate using different sized grains for a polycrystalline diamond substrate. The initial roughness varies from 10-50 nm. Conventional pads were utilized to achieve up to 3-5 nm of roughness with high within-wafer nonuniformity

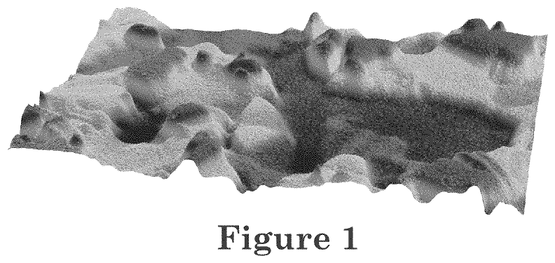

FIG. 2 is an optical profilometer 3D view of a polished polycrystalline diamond (PCD) substrate utilizing ultra-smooth PVC pads. In this Example, a roughness of about 0.3-1 nm can be achieved.

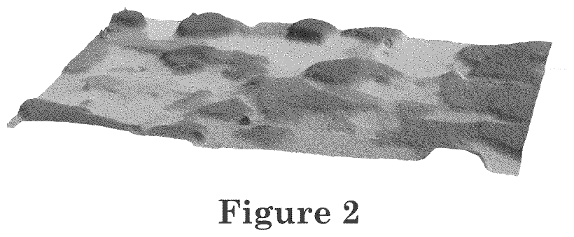

FIG. 3 is a depiction of the utilization of an ultra-smooth pad, with and without a standard polymeric pad backing.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a method for polishing a diamond surface, the method comprising:
a. contacting the surface with a slurry composition comprising abrasive particles effective for abrading a diamond surface;
b. moving the composition relative to the surface using a chemical mechanical polishing apparatus having a rotating polishing pad, wherein the pad has a surface roughness of about 0.2 to about 100 nm and a Shore D hardness of at least about 30, and
c. abrading the surface to remove a portion of the surface, thereby providing a polished diamond surface.

In one embodiment, the diamond surface comprises a single diamond crystal.

In one embodiment, the diamond surface comprises polycrystalline diamond (PCD).

In another aspect, the invention provides a method for polishing a polycrystalline alumina surface, the method comprising:
a. contacting the surface with a slurry composition comprising abrasive particles effective for abrading a polycrystalline alumina surface;
b. moving the composition relative to the surface using a chemical mechanical polishing apparatus having a rotating polishing pad, wherein the pad has a surface roughness of about 0.2 to about 100 nm and a Shore D hardness of at least about 30, and
c. abrading the surface to remove a portion of the surface, thereby providing a polished polycrystalline alumina surface.

In one embodiment, the polishing pad is comprised of a polymeric material. In one embodiment the polymeric material is chosen from poly(vinyl chloride), high density polyethylene (HDPE), and the like.

As noted above, the surface roughness (Ra) is about 0.2 to about 100 nm. In certain embodiments, the roughness is less than about 90, less than about 80, less than about 70, less than about 60, or less than about 50 nm.

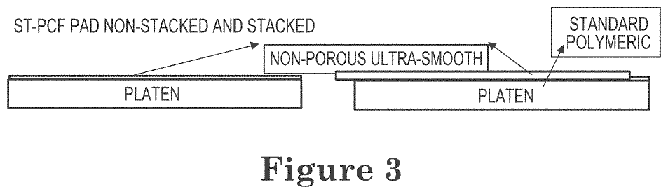

In one embodiment, the porosity of the pad is about 0-50 m·s/Kg. In one embodiment, the pad thickness is about 50 microns to about 15 mm. In one embodiment, the pad can be stacked or non-stacked, as depicted in FIG. 3; the base of the stacked pad can be a standard (hard or soft) polymeric pad.

In one embodiment, the slurry compositions effective for abrading a diamond surface are those which are known, many of which are commercially available. For example, slurry compositions comprising abrasives such as diamond, silicon carbide, alumina, silica, ceria, titania, zirconia, and the like can be utilized. Commercially available slurries include those containing diamond. Further examples of known slurries include those described in U.S. Pat. No. 9,567,492, incorporated herein by reference.

### EXAMPLES

Examples 1, 2 & 3 were performed on Buehler Automet-250, with platen RPM of 120 and head RPM of 60. The pressure used was 4 psi for the PolySiC, Poly Diamond and Poly-Crystalline Alumina. The slurry flow rate was maintained at 30 mL/min and the surface finish was measured on Wyko optical profilometer with scan size of 300 um×255 um size.

Example 4 is performed on the same parameters as above at different pressure conditions on the ST-PCF-B pad.

ST-PCF-B is a non-porous ultra-smooth pad with a standard polymeric pad backing, having a Shore-D of 70 and a surface roughness of about 55 nm (Ra).

### Example-1: Poly-Crystalline SiC Data on Different Pads with SND-9200-FA Slurry

| | Surface finish |
|---|---|
| Pad | Optical Profilometer |
| Suba-800 (DuPont) | 2.2 nm |
| IC-1000(DuPont) | 1.8 nm |
| D-100(Cabot) | 1.2 nm |
| ST-PCF-B | 0.5 nm |

### Example-2: Poly-Crystalline Diamond Data on Different Pads with SND-9200-FA Slurry

| | Surface finish |
|---|---|
| Pad | Optical Profilometer |
| Suba-800 | 4.6 nm |
| IC-1000 | 3.7 nm |
| D100 | 1.8 nm |
| ST-PCF-B | 0.8 nm |

### Example-3: Poly-Crystalline Alumina Data on Different Pads with SND-9500-PCA Slurry

| | Surface finish |
|---|---|
| Pad | Optical Profilometer |
| Suba-800 | 8.8 nm |
| IC-1000 | 5.8 nm |
| D100 | 5.2 nm |
| ST-PCF-B | 2.2 nm |

### Example-4: Poly-Crystalline SiC Data on ST-PCF-B Pad with SND-9200-FA Slurry with a Pressure Ladder

| | Surface finish |
|---|---|
| Pressure (psi) | Optical Profilometer |
| 2 | 0.7 nm |
| 4 | 0.5 nm |
| 6 | 0.4 nm |
| 8 | 0.6 nm |

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A method for polishing a diamond surface, the method comprising:
a. contacting the surface with a slurry composition comprising abrasive particles effective for abrading a diamond surface;
b. moving the composition relative to the surface using a chemical mechanical polishing apparatus having a rotating polishing pad, wherein the pad has a surface roughness of about 0.2 to about 100 nm and a Shore D hardness of at least about 30, and
c. abrading the surface to remove a portion of the surface, thereby providing a polished diamond surface.

2. The method of claim 1, wherein the diamond surface comprises a single diamond crystal.

3. The method of claim 1, wherein the diamond surface comprises polycrystalline diamond.

4. The method of claim 1, wherein the polishing pad is comprised of a polymeric material.

5. The method of claim 4, wherein the polymeric material is chosen from poly(vinyl chloride), high density polyethylene, and cross-linked polyethylene.

6. The method of claim 1, wherein the slurry composition comprises diamond abrasives.

7. A method for polishing a polycrystalline alumina surface, the method comprising:
a. contacting the surface with a slurry composition comprising abrasive particles effective for abrading a polycrystalline alumina surface;
b. moving the composition relative to the surface using a chemical mechanical polishing apparatus having a rotating polishing pad, wherein the pad has a surface roughness of about 0.2 to about 100 nm and a Shore D hardness of at least about 30, and
c. abrading the surface to remove a portion of the surface, thereby providing a polished polycrystalline alumina surface.

8. The method of claim 7, wherein the polishing pad is comprised of a polymeric material.

9. The method of claim 8, wherein the polymeric material is chosen from poly(vinyl chloride), high density polyethylene, and cross-linked polyethylene.

10. The method of claim 7, wherein the slurry composition comprises diamond abrasives.
